(19) United States
(12) Patent Application Publication
(10) Pub. No.: US 2013/0168862 A1
(43) Pub. Date: Jul. 4, 2013

(54) METHOD OF MANUFACTURING BARRIER LAYER PATTERNS OF A SEMICONDUCTOR MEMORY DEVICE AND STRUCTURE OF BARRIER LAYER PATTERNS OF SEMICONDUCTOR MEMORY DEVICE

(71) Applicant: Ha Chang JUNG, Icheon-si (KR)

(72) Inventor: Ha Chang JUNG, Icheon-si (KR)

(21) Appl. No.: 13/492,059

(22) Filed: Jun. 8, 2012

(30) Foreign Application Priority Data
Dec. 30, 2011 (KR) 10-2011-0146912

(51) Int. Cl. H01L 23/532; H01L 21/768; H01L 21/283

(52) U.S. Cl. 257/751; 438/585; 438/643; 257/E21.584; 257/E21.159; 257/E23.165

(57) ABSTRACT

A method of manufacturing a semiconductor memory and a structure of the semiconductor memory device, where the semiconductor memory device includes a material layer and a barrier layer. The barrier layer has a structure in which a horizontal cross-section of an upper portion thereof is larger than that of a lower portion thereof so that a fine pattern may be formed on the material layer using the barrier layer pattern without a structural damage or collapse in etching the underlying material layer.

### CROSS-REFERENCES TO RELATED APPLICATION

The present application claims priority under 35 U.S.C. 119(a) to Korean application number 10-2011-0146912, filed on Dec. 30, 2011 in the Korean Patent Office, which is incorporated by reference in its entirety.

### BACKGROUND OF THE INVENTION

1. Technical Field

The present invention relates to a method of manufacturing a semiconductor memory and a structure of the semiconductor memory device, and more particularly, to a method of manufacturing barrier layer patterns of a semiconductor memory device and a structure of barrier layer patterns thereof.

2. Related Art

Semiconductor devices configured to use for data storage are typically classified into volatile memory devices and nonvolatile memory devices.

Volatile memory devices such as random access memories (DRAMs) and static random access memories (SRAMs) have fast data input/output characteristics but stored data thereof is lost during power off. Nonvolatile memory devices such as NAND type or NOR type flash memories based on electrically erasable programmable read only memories (EEPROMs) retain data stored therein during power off. Here, data is written/erased in/from the nonvolatile memory device by using charge tunneling through a gate insulating layer, where an operation voltage higher than a power voltage is used. Thus, the flash memory device includes a booster circuit configured to generate a voltage for data writing or erasing. Thereby, design rule parameters are gradually increased due to implementation of the booster circuit.

With rapid development of information communication fields and rapid popularization of information media such as a computer, demands for next-generation semiconductor memories having ultra-high speed operation and a large memory storage capacity have increased.

To meet such demands, different types of semiconductor memory devices have been developed to combine advantages of volatile memory devices such as DRAMs and nonvolatile memory devices such as flash memories to obtain low power consumption and good data retention and data read/write operation characteristics. Examples of such semiconductor memory devices are ferroelectric random access memories (FRAMs), magnetic random access memories (RAMs), phase-change random access memories (PRAMs), or nano floating gate memories (NFGM).

As the integration degree of semiconductor devices is gradually increased and design rule parameters are reduced, patterns of semiconductor devices are desired to be finer.

As the integration degree of the semiconductor devices is increased, it is difficult to form fine patterns using a general photolithographic process. For example, as the integration of the semiconductor devices is increased, critical dimensions of patterns become smaller than a resolution of physical limits for exposure resolution so that it is more difficult to form photoresist patterns having a desired profile in a photolithographic process.

As a method of forming the fine patterns, there is a method of using a light source for exposure having short wavelength to improve a resolution when forming the photoresist (PR) patterns.

However, when the light source for exposure having a short wavelength is used, since a lot of light is absorbed in a PR layer and lost, the PR layer is thickly formed considering a loss amount. However, is when the PR layer is thickly formed, it is difficult for the light to arrive at a bottom of the PR layer. Thus, the PR layer is formed thinly in fabricating high-integration devices.

FIGS. 1A to 1C are cross-sectional views illustrating a method of forming fine patterns of a conventional semiconductor memory device.

First, referring to FIG. 1A, a material layer to be etched for form fine patterns is deposited on a semiconductor substrate 10 and subsequently a barrier layer 14 and an anti-reflection coating (ARC) 16 are sequentially deposited on the material layer 12. Here, the barrier layer 14 may be formed of spin on carbon (SOC), an amorphous carbon layer (ACL), or SION. A PR pattern 18 is formed on the ARC 16.

Referring to FIG. 1B, the ARC 16 and the barrier layer 14, which are deposited below the PR pattern 18, are sequentially etched anisotropically using the PR pattern 18 as a mask.

At this time, since the PR pattern 18 formed to be thin, the PR pattern 18 is partially lost in an etching process for the ARC 16 and the barrier layer 14 therebelow.

As a result, the anti-reflection coating (ARC) 16 and the barrier layer 14 below the PR pattern 18 are damaged and thus line width roughness (LWR) of the etched barrier layer pattern 14-1 is degraded (see “A” of FIG. 1B).

Referring to 1C, the material layer 12 below the etched barrier layer pattern 14-1 is anisotropically etched using the etched barrier layer pattern 14-1 as a self-aligned etch mask.

However, an upper portion of the material layer 12 is also damaged due to failure previously caused in the barrier pattern 14-1. As a result, failure such as collapse or notch is caused in the upper portion of the etched material pattern 12-1 (see “B” of FIG. 1C) so that reliability of the semiconductor memory device is degraded and thus a production yield is reduced.

FIG. 2 is a transmission electron microscope (TEM) photograph showing a state in which the barrier layer 14 is etched according to prior art.

Referring to FIG. 2, it is seen that line width roughness (LWR) of the barrier layer pattern 14-1 having a small area and a large deposition thickness due to the high integration of the semiconductor memory device is degraded. Thus, when the LWR of the barrier layer pattern is degraded, the underlying material layer 12-1, which is to be etched using the barrier layer pattern 14-1 as an etching mask, is also seriously damaged.

FIG. 3 is a scanning electron microscope (SEM) photograph showing a state in which the underlying material layer 12 is etched using the degraded barrier layer pattern 14-1 as shown in FIG. 2.

Referring to FIG. 3, the material layer is a conductive layer for a gate and it is seen that the degraded LWR of the barrier layer pattern 14-1 is transferred to the material layer 12 as it is so that an upper portion of the material layer 12-1 is also seriously damaged.

Thus, when the LWR of the barrier layer pattern 14-1 is degraded by a general etching process, the failure of the degraded barrier layer pattern 14-1 is transferred to the underlying material layer 12 and causes the pattern failure of the conductive material layer 12, where such a pattern failure affects electrical characteristics of the semiconductor memory device such as a gate or an interconnection. Therefore, reliability of the semiconductor memory device is degraded and thus a product yield is reduced.

According to an example, when the semiconductor memory device is manufactured, the barrier layer is thickly deposited to sufficiently ensure a margin of the barrier layer. As a height of the barrier layer is big within a restricted area, a structure of the barrier layer to be patterned becomes unstable.

In particular, when SOC having the softest material property among materials for the barrier layer is used as the barrier layer to minimize process costs, leaning or collapse of the barrier layer may occur in addition to thinning (see “A” of FIG. 1B) and the degradation in LWR of barrier layer due to the soft property of the SOC so that structural instability of the patterned barrier layer is further increased.

### SUMMARY

According to one aspect of an exemplary embodiment, a method of manufacturing barrier layer patterns of a semiconductor memory device includes forming a material layer on a semiconductor substrate, forming a barrier layer on the material layer; forming a PR pattern on the barrier layer; and performing an etching process on the barrier layer using the PR pattern to form a barrier layer pattern, wherein the barrier layer pattern has structures that each have an upper portion with a horizontal cross-section larger than a horizontal cross-section of a lower portion of the structure.

According to another aspect of an exemplary embodiment, a semiconductor memory device includes a material layer formed on a semiconductor substrate; and a barrier layer pattern formed on the material layer and used for an etch mask in etching the material layer, wherein the barrier layer pattern includes a structure with an upper portion having a horizontal cross-section larger than that of a lower portion of the structure.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1A to 1C are cross-sectional views illustrating a method of manufacturing fine patterns of a conventional semiconductor memory device;

FIG. 2 is a TEM photograph representing a state in which a barrier layer is etched according to prior art;

FIG. 3 is a SEM photograph representing a state in which an underlying material layer is etched using barrier layer patterns of FIG. 2;

FIGS. 4A to 4C are cross-sectional views illustrating a method of manufacturing barrier layer patterns of a semiconductor memory device according to an exemplary embodiment of the present invention;

FIGS. 5A to 5C are cross-sectional views illustrating a method of manufacturing barrier layer patterns of a semiconductor memory device according to another exemplary embodiment of the present invention;

FIG. 6 is a TEM photograph representing an etched state of a barrier layer pattern; and

FIG. 7 is a SEM photograph representing an etched state of fine patterns of a semiconductor memory device to which barrier layer patterns are applied.

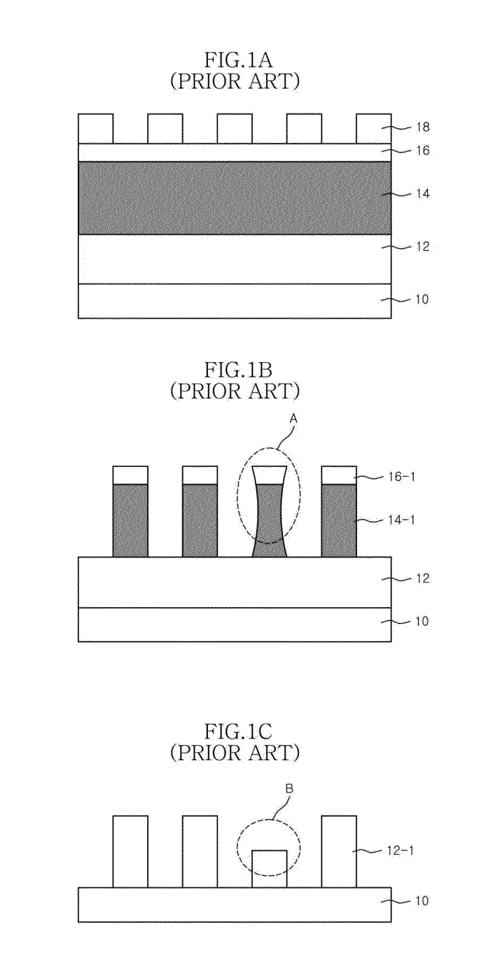

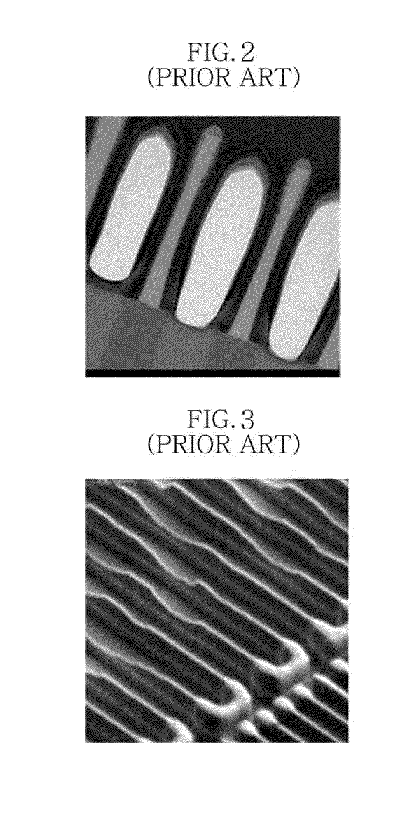

### DETAILED DESCRIPTION

Hereinafter, exemplary embodiments will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result of, for example, manufacturing techniques and/or tolerances are to be expected. Thus, exemplary embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

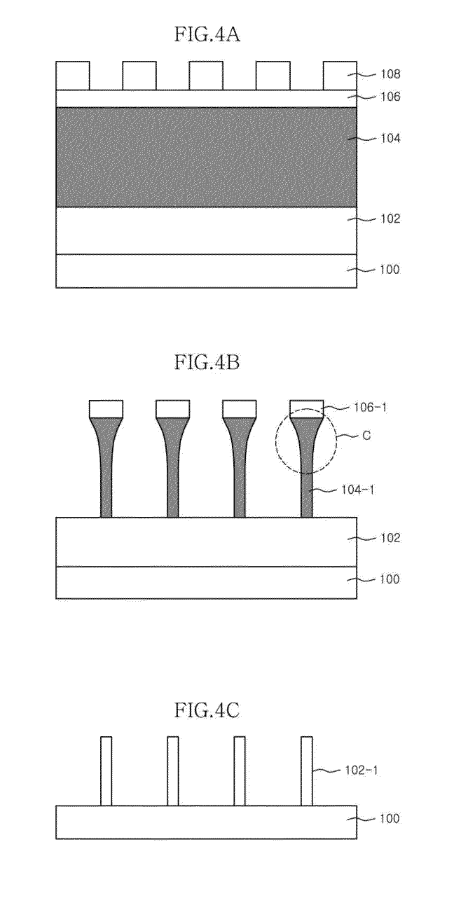

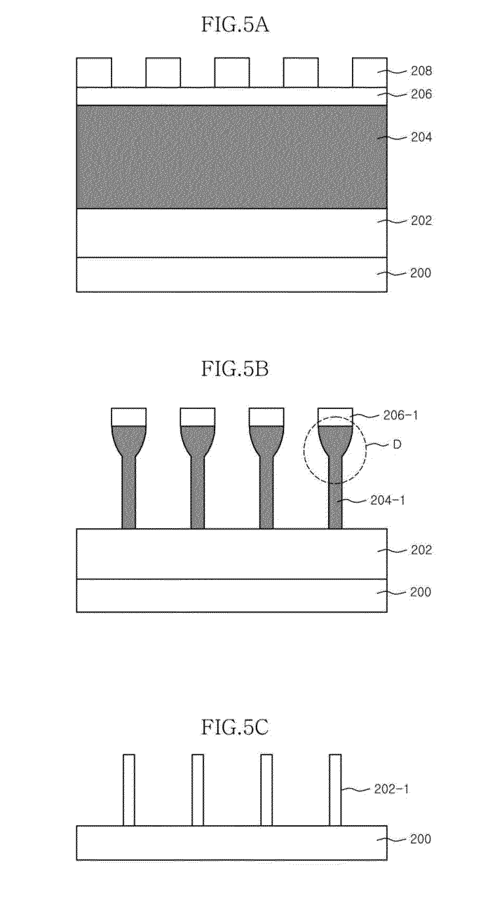

FIGS. 4A to 4C are cross-sectional views illustrating a method of manufacturing fine patterns of a semiconductor memory device according to an exemplary embodiment.

Referring to FIG. 4A, a material layer 102 to be etched into fine patterns is deposited on a semiconductor substrate 200. For example, the material layer 102 may include a conductive layer for a gate or interconnection.

Subsequently, a barrier layer 104 used for etching the material layer 102 and an anti-reflection coating (ARC) 106 are sequentially formed on the material layer 102. Here, the barrier layer 104 may be formed of a single layer including any one selected from the group consisting of PR, an amorphous carbon layer (ACL), and spin on carbon (SOC) or a compound layer including two or more selected from the group consisting of PR, an ACL, and SOC. A PR pattern 108 is formed on the ARC 106.

Referring to FIG. 4B, the ARC 106 and the barrier layer 104 deposited below the PR pattern 108 are sequentially etched anisotropically using the PR pattern 108 as an etch mask.

More specifically, first, an anisotropic etching process is performed on the ARC 106 using the PR pattern 108 as an etch mask. Subsequently, an anisotropic etching process according to an example is performed on the barrier layer 104 using the etched barrier layer pattern 106-1 as a self-aligned etch mask.

The anisotropic etching process for the barrier layer 104 is a dry etching process performed using plasma (or gas) under the etching condition as follows.

Source power of above 500 W and bias power of below 500 W are applied in a state that a pressure within a chamber in which a wafer is placed is maintained below 10 mT. Subsequently, plasma is formed using a mixture gas of HBr/O₂/N₂ and the barrier layer 104 is anisotropically etched at a plasma ambient.

When the anisotropic etching process is performed on the barrier layer 104 at the above-described ambient of the chamber, by-products of the barrier layer 104 generated in the etching process are attached to a sidewall of the barrier layer 104, more specifically, to an upper portion of the sidewall of the barrier layer 104. Thus, the barrier layer 104 is etched so that an area of an upper portion of the barrier layer 104 is larger than an area of a lower portion of the barrier layer 104. More specifically, the barrier layer 104 is etched to have an alphabet Y shape in which an upper area thereof (for example, a horizontal cross-section at an upper portion of the barrier layer 104) is larger than a lower area thereof (for example, a horizontal cross-section at a lower portion of the barrier layer 104). That is, as shown in “C” of FIG. 4B, the barrier layer 104 is etched to form a horn-shaped barrier pattern 104-1 which has a gradually curved-side profile from the top toward the bottom and of which an area is reduced from the top toward the bottom.

At this time, a shape of the barrier layer pattern 104-1 is changed depending on a flow of the HBr gas forming the plasma. The barrier layer pattern 104-1 is formed to have a structure suitable for forming fine patterns so that an upper portion of the barrier layer pattern 104-1 may occupy a half or less of a total area of the barrier layer pattern 104-1 and an area of the upper portion of the barrier layer pattern 104-1 may be larger than an area of a lower portion of the barrier layer pattern 104-1. More specifically, the area of the upper portion of the barrier layer pattern 104-1 may occupy 30% of a total area of the barrier layer pattern 104-1 and the area of the upper portion thereof may be larger than the area of the lower portion thereof. To obtain the structure of the barrier layer pattern 104-1, the flow of the HBr gas may be maintained at 100 to 200 sccm (Standard Cubic Centimeter per Minute).

Referring to FIG. 4C, the underlying material layer 102 is anisotropically etched using the etched barrier layer pattern 104-1 as a self-aligned etch mask. When the etching process for the material layer 102 is completed, the ARC pattern 106-1 and the barrier layer pattern 104-1 are removed.

As a result, fine material patterns 102-1 having a good profile and having no structural damage or collapse of the upper portion thereof can be obtained. The fine material patterns 102-1 may include a conductive pattern and may be used as a gate or an interconnection.

FIGS. 5A to 5C are cross-sectional views illustrating a method of manufacturing fine patterns of a semiconductor memory device according to another exemplary embodiment.

Referring to FIG. 5A, a material layer 202 to be etched into fine patterns is deposited on a semiconductor substrate 200. For example, the material layer 202 may include a conductive layer for a gate or interconnection.

Subsequently, a barrier layer 204 used for etching the material layer 202 and an ARC 206 are sequentially formed on the material layer 102. Here, the barrier layer 204 may be formed of a single layer including any one selected from the group consisting of PR, an ACL, and spin on carbon SOC or a compound layer including two or more selected from the group consisting of PR, an ACL, and SOC. A PR pattern 208 is formed on the ARC 206.

Referring to FIG. 5B, the ARC 206 and the barrier layer 204 deposited below the PR pattern 208 are sequentially etched anisotropically using the PR pattern 208 as an etch mask.

More specifically, first, an anisotropic etching process is performed on the ARC 206 using the PR pattern 208 as an etch mask. Subsequently, an anisotropic etching process according to an example is performed on the barrier layer 204 using the etched barrier layer pattern 206-1 as a self-aligned etch mask.

The anisotropic etching process for the barrier layer 204 is a dry etching process performed using plasma (or gas) under the etching condition as follows.

Source power of above 500 W and bias power of below 500 W are applied in a state that a pressure within a chamber in which a wafer is placed is maintained below 10 mT. Subsequently, plasma is formed using a mixture gas of HBr/O₂/N₂ and the barrier layer 204 is anisotropically etched at a plasma ambient.

When the anisotropic etching process is performed on the barrier layer 204 at the above-described ambient of the chamber, by-products of the barrier layer 204 generated in the etching process are attached to a sidewall of the barrier layer 204, more specifically, to an upper portion of the sidewall of the barrier layer 204. Thus, the barrier layer 204 is etched so that an area of an upper portion of the barrier layer 204 is larger than an area of a lower portion of the barrier layer 204. More specifically, the barrier layer 204 is etched to have an alphabet Y shape in which an upper area thereof is larger than a lower area thereof. That is, as shown in “D” of FIG. 5B, the barrier layer 104 is etched to form a wine-glass-shaped barrier pattern 204-1 having a side profile having a convex upper portion.

At this time, a shape of the barrier layer pattern 204-1 is changed depending on a flow of the HBr gas forming the plasma. The barrier layer pattern 204-1 is formed to have a structure suitable for forming fine patterns so that the an upper portion of the barrier layer pattern 204-1 may occupy a half or less of a total area of the barrier layer pattern 204-1 and an area of the upper portion of the barrier layer pattern 204-1 may be larger than an area of a lower portion of the barrier layer pattern 104-1. More specifically, the area of the upper portion of the barrier layer pattern 204-1 may occupy 30% of a total area of the barrier layer pattern 204-1 and the area of the upper portion thereof may be larger than the area of the lower portion thereof. To obtain the structure of the barrier layer pattern 204-1, the flow of the HBr gas may be maintained at 100 to 200 sccm.

Referring to FIG. 4C, the underlying material layer 202 is anisotropically etched using the etched barrier layer pattern 204-1 as a self-aligned etch mask. When the etching process for the material layer 202 is completed, the ARC pattern 206-1 and the barrier layer pattern 204-1 are removed.

As a result, fine material patterns 202-1 having a good profile and having no structural damage or collapse of the upper portion thereof can be obtained. The fine material patterns 202-1 may include a conductive pattern and may be used as a gate or an interconnection.

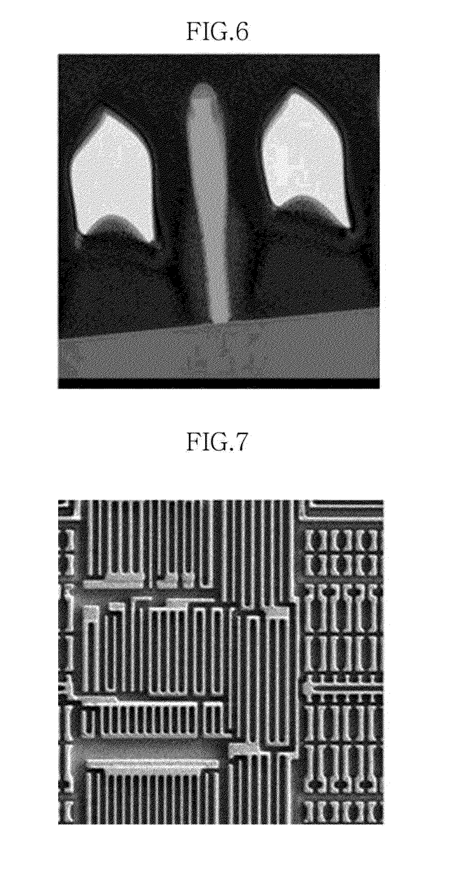

FIG. 6 is a TEM photograph representing an etched state of a barrier layer according to an exemplary embodiment.

When the anisotropic processes according to the exemplary embodiments are performed on the barrier layers 104 and 204, although the barrier layers 104 and 204 are thickly deposited within a restricted area due to high integration of semiconductor memory devices, the barrier layer patterns 104-1 and 204-1 having a good profile without degradation of LWR can be obtained.

FIG. 7 is a SEM photograph representing a state in which the underlying material layers 102 and 202 are etched using the barrier layer patterns 104-1 and 204-1.

When the underlying material layers 102 and 202 are etched using the barrier layer patterns 104-1 and 204-1 having a good profile as a self-aligned etch mask as shown in FIG. 6, adequate profiles of the underlying material layer patterns 102-1 and 202-1 are obtained as shown in FIG. 7.

The etched material layer patterns 102-1 and 202-1 is a minimum bar gate of a Y decoding area. Damage or collapse is not caused in the material layer patterns 102-1 and 202-1 and thus electric characteristics of the semiconductor memory device are improved.

As described above, a barrier layer is formed to have a structure in which an area of an upper portion thereof is larger than an area of a lower portion thereof so that the fine patterns having a good profile are formed without attack or collapse in etching the underlying material layer. Therefore, electrical characteristics of the semiconductor memory device are improved and an effect on increase in production yield is obtained.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A method of manufacturing barrier layer patterns of a semiconductor memory device, comprising:
forming a material layer on a semiconductor substrate;
forming a barrier layer on the material layer;
forming a photoresist (PR) pattern on the barrier layer; and
performing an etching process on the barrier layer using the PR pattern to form a barrier layer pattern, wherein the barrier layer pattern has structures that each have an upper portion with a horizontal cross-section larger than a horizontal cross-section of a lower portion of the structure.

2. The method of claim 1, wherein the barrier layer is formed of a single layer including any one selected from the group consisting of a photoresist (PR) layer, an amorphous carbon layer (ACL), and spin on carbon (SOC) or a compound layer including two or more selected from the group consisting of a PR layer, an ACL, and SOC.

3. The method of claim 2, wherein the barrier layer is etched using plasma formed by using a mixture gas of HBr/O₂/N₂ while applying source power of above 500 W and bias power of below 500 W under a chamber pressure below 10 mT.

4. The method of claim 3, wherein a flow of the HBr gas is maintained at 100 to 200 sccm.

5. The method of claim 4, wherein the structures of the barrier layer pattern each form an alphabet Y shape in which a horizontal cross-section of the upper portion thereof is substantially larger than that of the lower portion thereof.

6. The method of claim 5, wherein the structures of the etched barrier layer pattern each have a curved-side profile vertically so that a width of the structure decreases as the structure extends from the top toward the bottom.

7. The method of claim 6, further comprising forming an anti-reflection coating (ARC) on the barrier layer.

8. The method of claim 5, wherein the alphabet Y shape has a wine glass-shaped side profile having a convex upper portion.

9. The method of claim 8, further comprising forming an anti-reflection coating (ARC) on the barrier layer.

10. A semiconductor memory device, comprising:
a material layer formed on a semiconductor substrate; and
a barrier layer pattern formed on the material layer and used for an etch mask in etching the material layer, wherein the barrier layer pattern includes a structure with an upper portion having a horizontal cross-section larger than that of a lower portion of the structure.

11. The semiconductor memory device of claim 10, wherein the barrier layer is formed of a single layer including any one selected from the group consisting of a photoresist (PR) layer, an amorphous carbon layer (ACL), and a spin on carbon (SOC) or a compound layer including two or more selected from the group consisting of a PR layer, an ACL layer, and a SOC layer.

12. The semiconductor memory device of claim 11, wherein the structure forms an alphabet Y shape in which a horizontal cross-section of the upper portion thereof is substantially larger than that of the lower portion thereof.

13. The semiconductor memory device of claim 12, wherein the structure has a curved-side profile vertically so that a width of the structure decreases as the structure extends from the top toward the bottom.

14. The semiconductor memory device of claim 12, wherein the alphabet Y shape has a wine glass-shaped side profile having a convex upper portion.
